(19) United States
(12) Patent Application Publication
(10) Pub. No.: US 2011/0235301 A1
(43) Pub. Date: Sep. 29, 2011

(54) HEAT DISSIPATION APPARATUS AND ELECTRONIC ASSEMBLY WITH SAME

(75) Inventors: YI-SHIH HSIEH, Tu-Cheng (TW); YONG-JIAN WANG, KunShan (CN)

(73) Assignees: FURUI PRECISE COMPONENT (KUNSHAN) CO., LTD., KunShan City (CN); FOXCONN TECHNOLOGY CO., LTD., Tu-Cheng (TW)

(21) Appl. No.: 12/765,783

(22) Filed: Apr. 22, 2010

(30) Foreign Application Priority Data
Mar. 24, 2010 (CN) 201010131748.7

(51) Int. Cl. H05K 7/14; F28F 7/00

(52) U.S. Cl. 361/809; 165/185

(57) ABSTRACT

A heat dissipation apparatus includes a base plate and a plurality of fasteners. A plurality of mounting arms extends outwardly from the base plate. Each mounting arm defines a through hole therein. An inner thread is formed on an inner surface of each through hole. Each fastener includes a main post, a cap formed at a top of the main post, and an engaging portion formed at a bottom of the main post. A retaining thread is formed on an outer surface of the main post adjacent the engaging portion. The retaining thread matches the inner thread of the through hole of the corresponding mounting arm. The retaining thread is passable through the through hole of the mounting arm by threadingly passing the retaining thread through the inner thread of the through hole of the mounting arm whereupon the fastener remains preassembled in the through hole.

### BACKGROUND

1. Technical Field

The present disclosure generally relates to heat dissipation, and particularly to a heat dissipation apparatus for electronic components.

2. Description of Related Art

With developments in technology, increased performance of electronic components such as CPUs (central processing units) has been achieved. However, such electronic components generate increased levels of heat, which must be dissipated promptly. Conventionally, a base plate is attached to an electronic component to remove the generated heat. The base plate is attached on a circuit board on which the electronic component is mounted.

The base plate generally defines a plurality of through holes therein. The circuit board defines a plurality of receiving holes therein, corresponding to the through holes of the base plate. A plurality of fasteners such as screws pass respectively through the through holes of the base plate and are received in the receiving holes of the circuit board to secure the base plate to the electronic component.

In general, before the base plate is secured to the circuit board, the fasteners are preassembled to the base plate. To maintain the fasteners on the base plate, a gasket is generally clipped onto a bottom portion of each fastener after the fastener extends through the base plate. However, the gaskets increase the cost of the base plate. In addition, a tool is often needed to clip each gasket onto the fastener. Furthermore, after the base plate is secured to the circuit board, the gaskets have no further use, and may even drop down onto circuitry of the circuit board. If a gasket is made of electrically conductive material, it is liable to cause a short circuit when it drops down.

Therefore, what is needed is a heat dissipation apparatus which can overcome the described limitations.

### BRIEF DESCRIPTION OF THE DRAWINGS

FIG. 1 is an isometric, assembled view of a heat dissipation apparatus in accordance with an embodiment of the present disclosure.

FIG. 2 is an enlarged, cross-sectional view of part of the heat dissipation apparatus of FIG. 1, corresponding to line thereof, but showing certain components detached from each other.

FIG. 3 is an enlarged, cross-sectional view of the same part of the heat dissipation apparatus of FIG. 1, taken along the line thereof.

### DETAILED DESCRIPTION

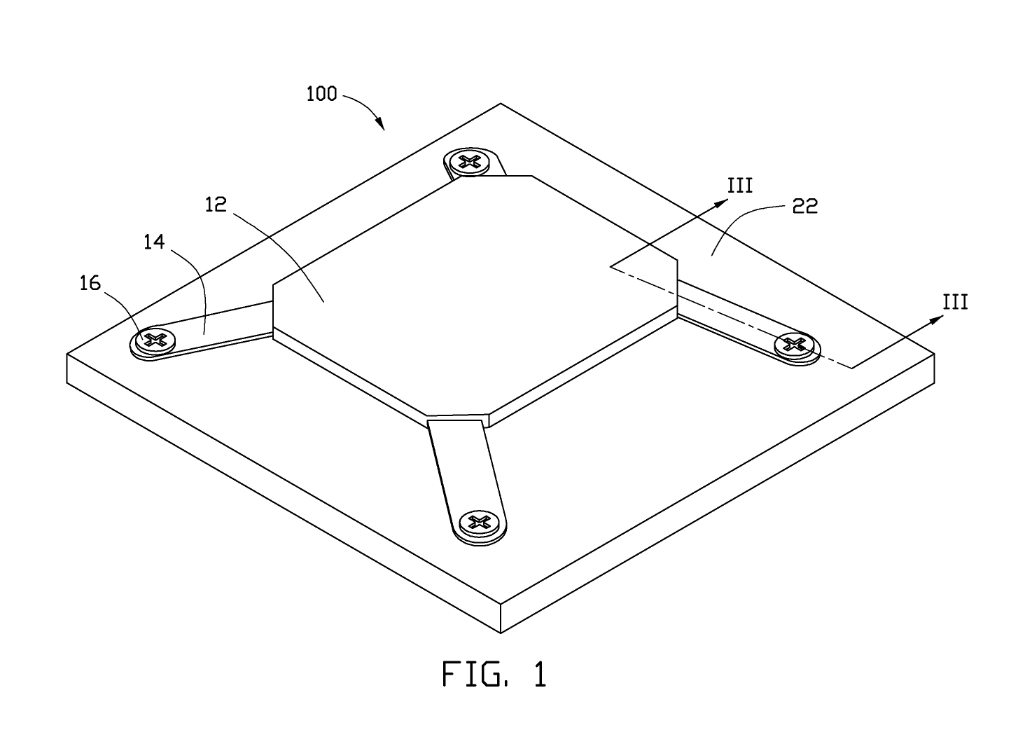

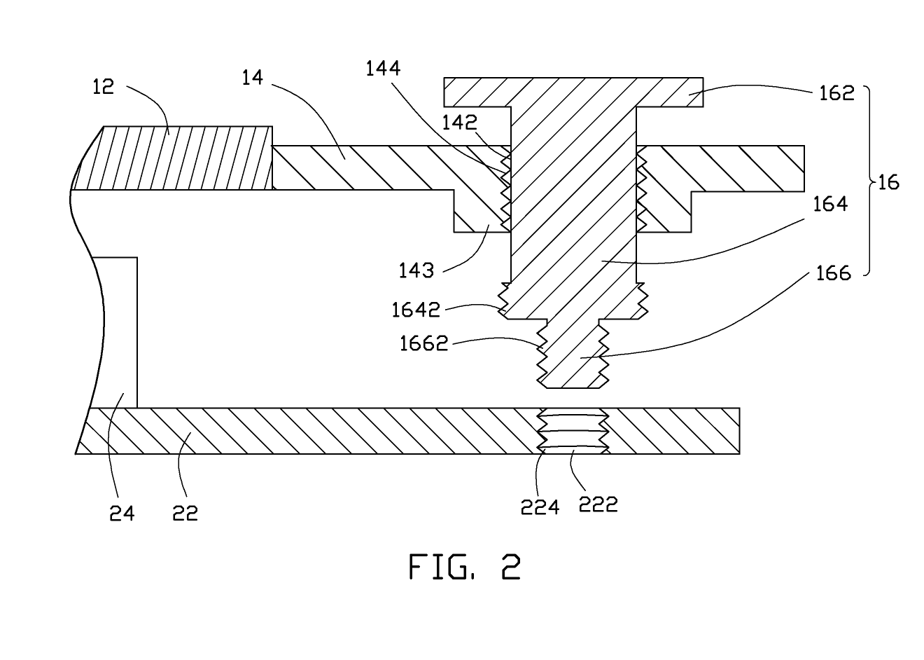

Referring to FIGS. 1 and 2, a heat dissipation apparatus 100 according to an embodiment of the present disclosure is shown. The heat dissipation apparatus 100 is configured for dissipating heat from an electronic component 24 mounted on a circuit board 22 of a computer. The electronic component 24 may for example be a CPU (central processing unit), and the computer may for example be a notebook computer. The heat dissipation apparatus 100 includes a base plate 12, and a plurality of fasteners 16 for fixing the base plate 12 on the circuit board 22 on which the electronic component 24 is mounted. A plurality of receiving holes 222 is defined in the circuit board 22 around the electronic component 24. An inner thread 224 is formed on an inner surface of each receiving hole 222.

Four mounting arms 14 extend horizontally from four corners of the base plate 12, respectively. A bottom surface of the base plate 12 is configured to be attached to the electronic component 24 to absorb heat therefrom. A through hole 142 is defined in each mounting arm 14, near a free end of the mounting arm 14. The through holes 142 are coaxial with the receiving holes 222 of the circuit board 22. An inner thread 144 is formed on an inner surface of each through hole 142. The fasteners 16 are preassembled in the through holes 142 of the mounting arms 14 of the base plate 12.

Each fastener 16 includes a main post 164, a cap 162 formed at a top end of the main post 164, and a engaging portion 166 formed at a bottom end of the main post 164. The cap 162 has a diameter greater than that of the main post 164. The engaging portion 166 has a diameter less than that of the main post 164. The main post 164 has a diameter slightly less than that of the through hole 142 of the base plate 12. The engaging portion 166 has a diameter substantially the same as that of the corresponding receiving hole 222 of the circuit board 22. An outer thread 1662 is formed on an outer surface of the engaging portion 166, for engaging the inner thread 224 of the receiving hole 222 of the circuit board 22.

A retaining thread 1642 is formed on an outer surface of a bottom portion of the main post 164 adjacent the engaging portion 166. The retaining thread 1642 matches the inner thread 144 of the corresponding through hole 142 of the base plate 12. The bottom portion of the main post 164 can pass through the through hole 142 of the base plate 12 by threadingly passing the retaining thread 1642 of the bottom portion of the main post 164 through the inner thread 144 of the through hole 142. After the retaining thread 1642 has passed through the through hole 142, the main post 226 is held in the through hole 142 by the cap 162 located above the through hole 142 and the bottom portion of the main post 164 located below the through hole 142. Thus, the fasteners 16 remain with the base plate 12 during transport.

In the present embodiment, a collar 143 depends from a bottom surface of each mounting arm 14 at each through hole 142. That is, the through hole 142 spans through both a main portion of the mounting arm 14 and the collar 143, and the inner thread 144 of the inner surface of the through hole 142 correspondingly spans through both the main portion of the mounting arm 14 and the collar 143. With the collar 143, the inner thread 144 has a greater length and more capability to match and engage the retaining thread 1642 of the bottom portion of the main post 164. Thus, the fastener 16 can be preassembled to the base plate 12 more easily and securely.

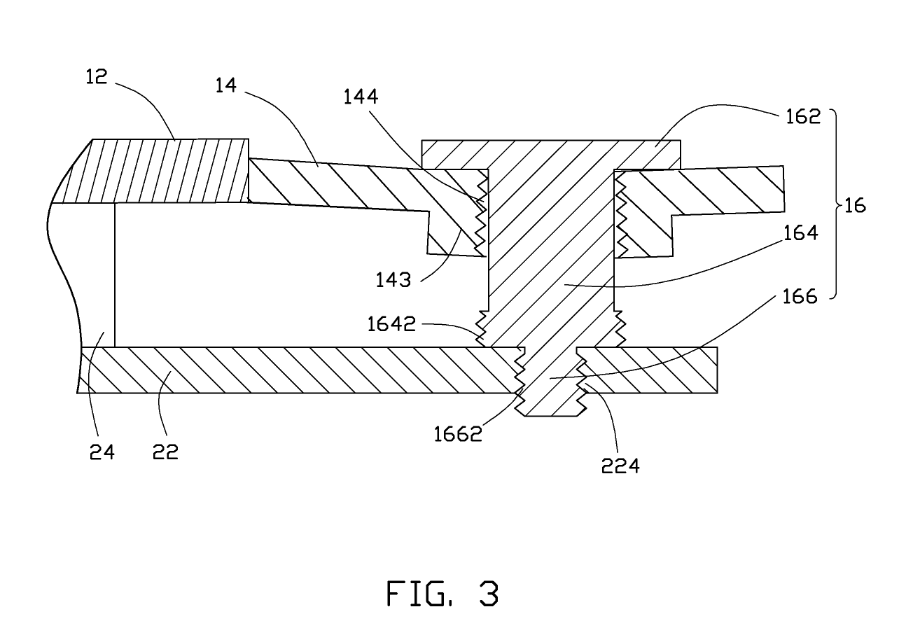

In assembling the base plate 12 to the circuit board 22, the engaging portion 166 of each fastener 16 is received in the corresponding receiving hole 222 of the circuit board 22, and secures the base plate 12 to the electronic component 24, as shown in FIG. 3. The cap 162 of the fastener 16 abuts the mounting arm 14. Typically, the mounting arm 14 is deformed slightly downwardly by the cap 162 to generate a downward force impelling the base plate 12 downwardly towards the electronic component 24.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation apparatus, comprising:
a base plate comprising a plurality of mounting arms extending outwardly therefrom, each mounting arm defining a through hole at a free end thereof, an inner thread formed on an inner surface of each through hole; and
a plurality of fasteners preassembled respectively in the through holes of the mounting arms, each fastener comprising a main post, a cap formed at a top portion of the main post, and a engaging portion formed at a bottom of the main post;
wherein a retaining thread is formed on an outer surface of the main post adjacent the engaging portion, the retaining thread of the main post matches the inner thread of the through hole of the corresponding mounting arm, the retaining thread of the main post is passable through the through hole of the mounting arm by threadingly passing the retaining thread through the inner thread of the through hole whereupon the fastener remains preassembled in the through hole.

2. The heat dissipation apparatus of claim 1, wherein the fastener remains preassembled in the through hole by cooperation of the cap above the mounting arm and the portion of the main post having the retaining thread below the mounting arm.

3. The heat dissipation apparatus of claim 1, wherein the base plate is substantially rectangular, and the mounting arms extend outwardly from four corners of the base plate.

4. The heat dissipation apparatus of claim 1, wherein a collar is formed on each mounting arm at each through hole, and the through hole and the inner thread of the inner surface of the through hole span through the mounting arm including the collar.

5. The heat dissipation apparatus of claim 1, wherein the engaging portion of the fastener has a diameter less than that of the main post of the fastener, and an outer thread is formed on an outer surface of the engaging portion of the fastener.

6. An electronic assembly, comprising:
a circuit board defining a plurality of receiving holes therein;
an electronic component mounted on the circuit board;
a base plate mounted on the electronic component, the base plate comprising a plurality of mounting arms extending outwardly therefrom, each mounting arm defining a through hole at a free end thereof, and an inner thread formed on an inner surface of each through hole; and
a plurality of fasteners attached in the through holes of the mounting arms, each fastener comprising a main post, a cap formed at a top of the main post, and a engaging portion formed at a bottom of the main post, the engaging portion of each fastener received in a corresponding receiving hole of the circuit board, the cap abutting the corresponding mounting arm and exerting a downward force urging the base plate towards the electronic component;
wherein a retaining thread is formed on an outer surface of the main post adjacent the engaging portion, the retaining thread of the main post matching the inner thread of the through hole of the corresponding mounting arm, and the retaining thread of the main post configured to pass down through the through hole of the mounting arm by threadingly passing the retaining thread of the main post through the inner thread of the through hole whereupon the fastener remains preassembled in the through hole.

7. The electronic assembly of claim 6, wherein the fastener remains preassembled in the through hole by cooperation of the cap above the mounting arm and the portion of the main post having the retaining thread below the mounting arm.

8. The electronic assembly of claim 6, wherein the base plate is substantially rectangular, and the mounting arms extend outwardly from four corners of the base plate.

9. The electronic assembly of claim 6, wherein a collar is formed on each mounting arm at each through hole, and the through hole and the inner thread of the inner surface of the through hole span through the mounting arm including the collar.

10. The electronic assembly of claim 6, wherein the engaging portion of each fastener has a diameter less than that of the main post of the fastener, an outer thread is formed on an outer surface of the engaging portion of the fastener, and an inner thread is formed on an inner surface of the respective receiving hole of the circuit board corresponding to the outer thread of the engaging portion of the fastener.
